(19) United States
(12) Patent Application Publication
(10) Pub. No.: US 2024/0363345 A1
(43) Pub. Date: Oct. 31, 2024

(54) SILICON CHANNEL FOR BONDED 3D NAND DEVICES

(71) Applicant: Applied Materials, Inc., Santa Clara, CA (US)

(72) Inventors: Chang Seok KANG, San Jose, CA (US); Raman GAIRE, Mechanicville, NY (US); Hsueh Chung CHEN, Cohoes, NY (US); In Soo JUNG, Campbell, CA (US); Houssam LAZKANI, Schenectady, NY (US); Balasubramanian PRANATHARTHIHARAN, Santa Clara, CA (US)

(73) Assignee: Applied Materials, Inc., Santa Clara, CA (US)

(21) Appl. No.: 18/441,352

(22) Filed: Feb. 14, 2024

Related U.S. Application Data
(60) Provisional application No. 63/462,462, filed on Apr. 27, 2023.

(51) Int. Cl. H01L 21/02; H01L 21/20; H01L 21/306

(52) U.S. Cl. CPC H01L 21/02645; H01L 21/02532; H01L 21/2003; H01L 21/306

(57) ABSTRACT

A method for manufacturing a memory device includes depositing a seed layer in a memory hole extending through a memory stack. The seed layer includes particles, such as silicon particles. The seed layer is etched to produce etched particles. The etched particles act as nuclei for the growth of a crystalline channel material in the memory hole.

### CROSS-REFERENCE TO RELATED APPLICATIONS

This application claims benefit of U.S. Provisional patent application No. 63/462,462, filed Apr. 27, 2023, which is incorporated herein by reference in its entirety.

### BACKGROUND

### Field

Embodiments of the present disclosure generally relate to the field of electronic devices, and methods for manufacturing electronic devices. More particularly, embodiments of the present disclosure concern memory devices, such as 3D-NAND devices.

### Description of the Related Art

Memory devices, such as 3D-NAND devices have a memory stack disposed on a substrate. The memory stack includes alternating layers of an oxide material and a nitride material. Multiple memory holes extend through the memory stack to the substrate. Typically, the memory holes are filled with a channel material, such as silicon alone or a silicon sleeve surrounding a silicon oxide core. The effective functioning of the memory device depends on the magnitude of the electric current (“string current”) that passes through the channel material of each memory hole. Too small a string current may result in a failure of a computer processor to read the memory stored in a memory device.

There is a need for memory devices that have a greater memory capacity than current devices. Typically, such a need is met by increasing the number of layers in a memory stack and/or increasing the number of memory holes. However, there is a competing need for memory devices that are sized similarly to, or smaller than, present-day memory devices. Such a need may be met by reducing the diameter of the memory holes. In balancing the respective needs, there is a trend towards memory devices having longer and/or thinner memory holes. Making memory holes longer and/or thinner reduces the current-carrying capacity of the channel material of each memory hole, and raises a consequential risk that a processor would fail to read the memory stored in a memory device.

Thus, there is a need for processes for the manufacture of memory devices incorporating an improved quality of channel material that facilitates the effective passage of reduced string currents.

### SUMMARY

The present disclosure concerns methods for manufacturing electronic devices, particularly memory devices, such as 3D-NAND devices. In one implementation, a substrate processing method includes depositing a seed layer of particles onto a floor and a sidewall of a memory hole extending through a memory stack. The method further includes etching the seed layer to produce etched particles, and growing crystals on the floor and on the sidewall of the memory hole. The etched particles act as nuclei for growing the crystals.

In another implementation, a substrate processing method includes depositing a seed layer of particles onto a dielectric material lining a memory hole extending through a memory stack disposed on a front side of a substrate. The method further includes etching the seed layer to produce etched particles, and growing a plurality of crystals in the memory hole. The etched particles act as nuclei for growing the crystals.

In another implementation, a method of manufacturing a memory device includes forming a memory stack on a front side of a substrate, forming a memory hole through the memory stack and into the substrate, and placing a channel material in the memory hole within the memory stack. The placing of the channel material in the memory hole within the memory stack includes depositing a seed layer of particles in the memory hole, etching the seed layer to produce etched particles, and growing crystals in the memory hole. The etched particles act as nuclei for growing the crystals.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 schematically illustrates a cross-section of a portion of a memory device.

FIGS. 2A to 2F schematically illustrate a cross-section of a portion of a memory device at various phases of manufacture.

FIGS. 3A to 3D schematically illustrate a cross-section of a portion of a memory device at various phases of manufacture.

FIG. 4 is a flow diagram of a method of processing a substrate.

FIG. 5 is a flow diagram of a method of processing a substrate.

FIG. 6 is a flow diagram of a method of manufacturing a memory device.

FIGS. 7A and 7B schematically represent particles of a seed layer respectively before and after an etching operation.

FIGS. 8A and 8B schematically represent comparisons of crystal sizes and numbers for channel material deposited under two different scenarios.

FIG. 9 is a graph schematically representing magnitudes of string current through memory holes containing different channel materials.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure concerns methods for manufacturing electronic devices, particularly memory devices, such as 3D-NAND devices.

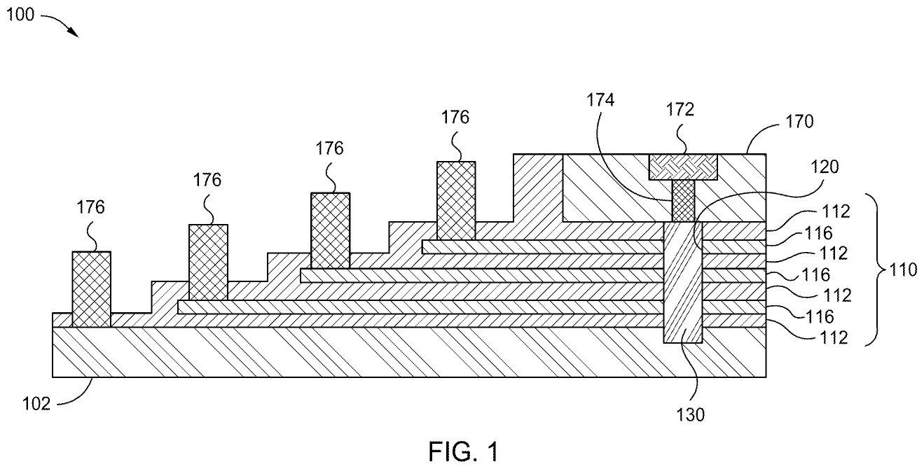

FIG. 1 schematically illustrates a cross-section of a portion of a memory device 100. The memory device 100 includes a substrate 102. In some embodiments, the substrate 102 is made of silicon. In an example, the silicon is doped, such as an N+ type doping. A memory stack 110 is disposed on the substrate 102. The memory stack 110 includes an alternating sequence of dielectric layers 112 (such as a silicon oxide, such as SiO₂) and word lines 116. Although only a few layers 112 and word lines 116 are shown in the memory stack 110, it is contemplated that the memory stack 110 may include tens or hundreds of layers 112 and word lines 116.

A memory hole 120 extends through the memory stack 110 and penetrates into the substrate 102. Although only one memory hole 120 is shown, it is contemplated that the memory device 100 includes a plurality of memory holes 120. Each memory hole 120 contains a channel material 130, such as silicon, such as polysilicon. A metalized layer 170 is disposed on the memory stack 110. The metalized layer 170 may contain any one or more of aluminum, nickel, chromium, gold, germanium, copper, silver, titanium, tungsten, platinum, tantalum, or alloys thereof. The metalized layer 170 includes a contact 174 and a bit line 172. The contact 174 is metallic, for example copper or tungsten. The contact 174 forms an electrical connection between the channel material 130 and the bit line 172. The bit line 172 is metallic, for example copper or tungsten. The memory device 100 includes additional contacts 176, each of which are coupled to individual word lines 116 or to the substrate 102. The additional contacts 176 are metallic, for example copper or tungsten.

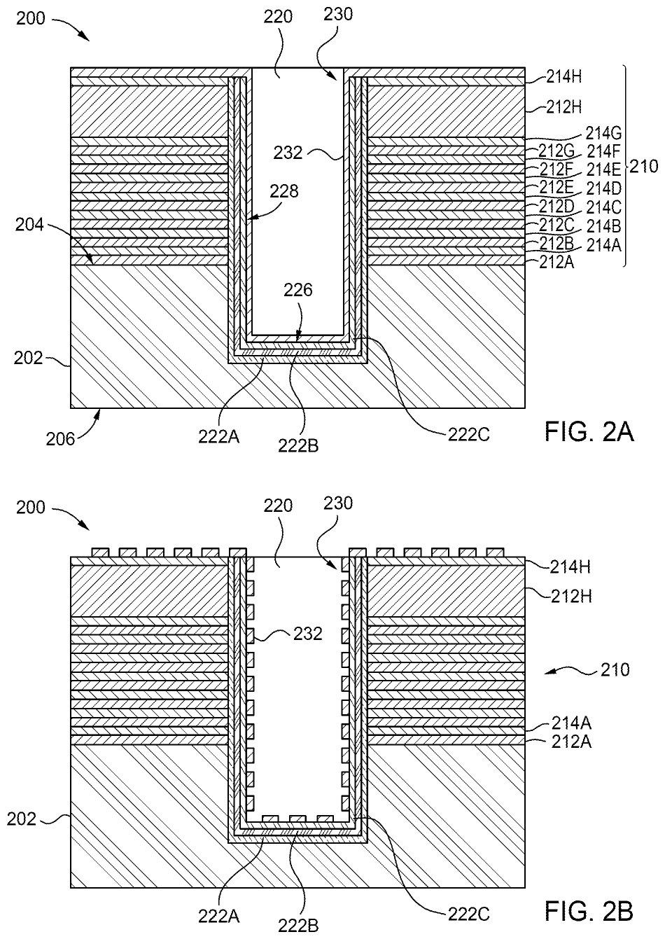

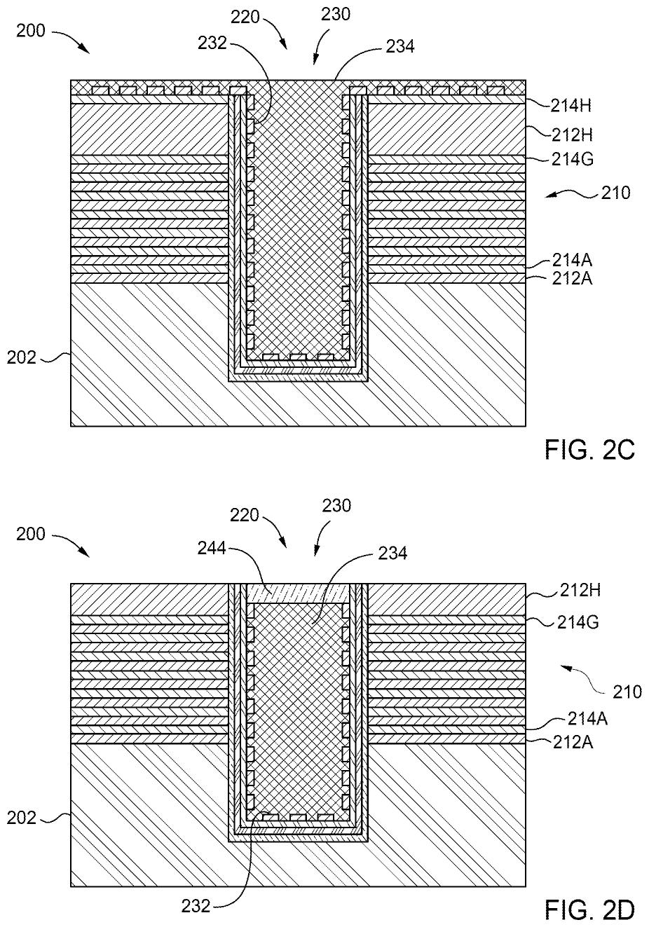

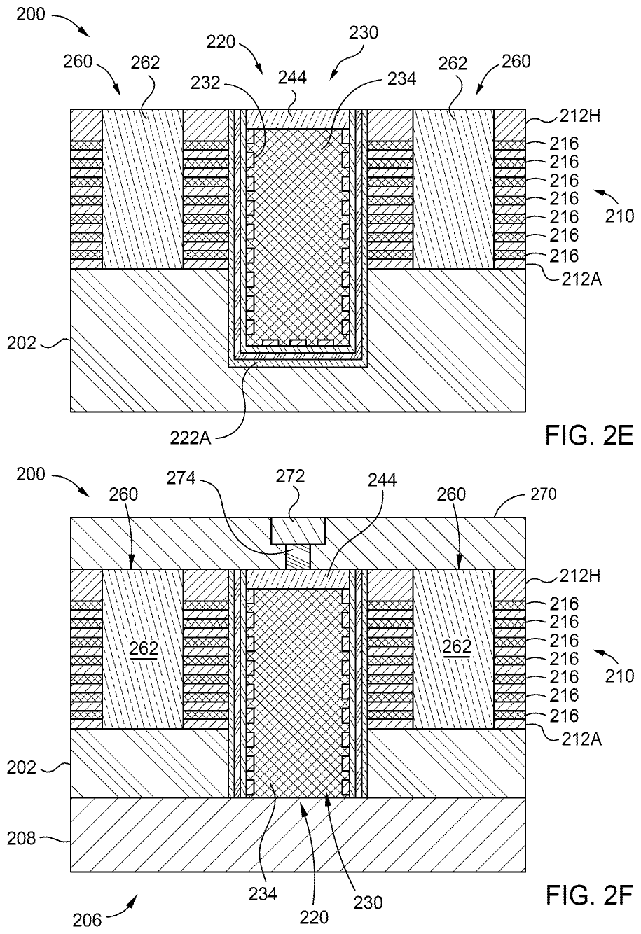

FIGS. 2A to 2F schematically illustrate a cross-section of a portion of a memory device 200 at various phases of manufacture. Memory device 200 may represent the memory device 100 of FIG. 1. The memory device 200 includes a substrate 202. In some embodiments, the substrate 202 is made of silicon. A memory stack 210 is disposed on a front side 204 of the substrate 202. The memory stack 210 includes an alternating sequence of dielectric layers 212, 214. A first layer of a silicon oxide (such as SiO₂) 212A is disposed on the substrate 202, and a first layer of a silicon nitride (such as SiN₂ or Si₅N₄) 214A is disposed on the layer of silicon oxide 212A. Further layers of silicon oxide 212B-H alternating with further layers of silicon nitride 214B-H are disposed on the first layer of silicon nitride 214A. Although only a few layers 212, 214 are shown, it is contemplated that the memory stack 210 may include tens or hundreds of layers 212, 214.

A memory hole 220 extends through the memory stack 210 and penetrates into the substrate 202. Although only one memory hole 220 is shown, it is contemplated that the memory device 200 includes a plurality of memory holes 220. An exemplary critical dimension of the memory hole 220 is a diameter of the memory hole 220, and is from about 50 nm to about 150 nm, such as from about 65 nm to about 135 nm, such as from about 80 nm to about 120 nm, such as about 100 nm.

The memory hole 220 is lined with a dielectric material. A first liner layer of a silicon oxide (such as SiO₂) 222A contacts the substrate 202 and the layers 212, 214 of the memory stack 210. In some embodiments, the first liner layer 222A is created by a conformal atomic layer deposition (ALD) process. A second liner layer of a silicon nitride (such as SiN₂ or Si₃N₄) 222B is disposed on the first liner layer 222A. In some embodiments, the second liner layer 222B is created by a conformal ALD process. A third liner layer of a silicon oxide (such as SiO₂) 222C is disposed on the second liner layer 222B. In some embodiments, the third liner layer 222C is created by a conformal ALD process.

A seed layer 232 of channel material 230 is shown deposited onto a floor 226 and a sidewall 228 of the memory hole 220. In the illustrated example, the seed layer 232 is deposited onto the third liner layer 222C at the floor 226 and sidewall 228 of the memory hole 220. A thickness of the seed layer 232 is from about 1 nm to about 20 nm, such as from about 1 nm to about 15 nm, such as from about 1 nm to about 10 nm, such as about 5 nm.

In some embodiments that may be combined with other embodiments, the seed layer 232 includes particles of silicon. In some embodiments that may be combined with other embodiments, the seed layer 232 may include particles of one or more other substances, such as germanium. In some embodiments that may be combined with other embodiments, the seed layer 232 is deposited using a thermal chemical deposition process, such as chemical vapor deposition. In an example, the seed layer 232 is deposited by exposing the memory hole 220 to a silicon precursor in a hydrogen environment at about 400° C. to about 1100° C. for an exposure time of about 10 seconds to about 10 minutes. In some embodiments that may be combined with other embodiments, the precursor includes at least one of silane, dichlorosilane (DCS), trichlorosilane (TCS), or a silene.

FIG. 2B represents the result of an etching operation on the seed layer 232. The etching operation is conducted by exposing the seed layer 232 to an acid, such as hydrochloric acid. In some embodiments, the etching operation and the seed layer 232 deposition operation are conducted in the same processing chamber. In some embodiments, the etching operation and the seed layer 232 deposition operation are conducted in different processing chambers.

In some embodiments that may be combined with other embodiments, the etching operation reduces an average size of the particles of the seed layer 232. In an example, an average particle diameter is reduced from about 2 to 10 nm before etching to about 1 to 2 nm after etching, such as from about 4 to 6 nm before etching to about 1 to 2 nm after etching. In some embodiments that may be combined with other embodiments, the etching operation reduces an area number density of the particles (i.e., reduces the number of particles per unit area). In an example, an area number density of the particles after etching is about 30 to 70 percent, such as about 40 to 60 percent, such as about 50 percent, of the area number density of the particles before etching.

In FIG. 2C, the channel material 230 is shown as including a fill material 234 filling the memory hole 220. In some embodiments that may be combined with other embodiments, the fill material 234 includes silicon, and may be referred to as a silicon channel or a polysilicon channel. In some embodiments that may be combined with other embodiments, the fill material 234 may include one or more other substances, such as germanium. In some embodiments that may be combined with other embodiments, the fill material 234 is deposited using a thermal chemical deposition process, such as chemical vapor deposition. In an example, the fill material 234 is deposited by exposing the memory hole 220 to a silicon precursor in a hydrogen environment at about 400° C. to about 1100° C. for an exposure time of about one minute to about 30 minutes. In some embodiments that may be combined with other embodiments, the precursor includes at least one of silane, dichlorosilane (DCS), trichlorosilane (TCS), or a silene.

Deposition of the fill material 234 includes growing crystals, such as silicon crystals. In embodiments in which the seed layer 232 includes one or more other substances, such as germanium, the crystals may include germanium crystals or SiGe crystals. The particles of the seed layer 232 remaining after the etching operation act as nuclei for growing the crystals. Although the seed layer 232 is depicted in the Figure, in some embodiments that may be combined with other embodiments, the seed layer 232 effectively becomes part of the fill material 234.

FIG. 2D shows the memory device 200 after further phases of manufacture. The memory device 200 is shown having undergone a planarization process. Planarization, such as by chemical mechanical polishing, removes extraneous material that had been deposited on the top of the memory device 200. As illustrated, the planarization removes also the uppermost silicon nitride layer 214H of the memory stack 210, leaving the uppermost silicon oxide layer 212H exposed.

Thereafter, an upper portion 244 of the channel material 230 is implanted with a dopant. In some embodiments that may be combined with other embodiments, the doping is N+ type. In an example that may be combined with other examples, the dopant is one or more of phosphorus, arsenic, or antimony. In an example that may be combined with other examples, a doping density is from about 10¹⁹ cm⁻³ to about 5×10²⁰ cm⁻³. In an example that may be combined with other examples, a doping energy is from about 10 keV to about 50 keV, such as from about 20 keV to about 40 keV, such as about 30 keV.

FIG. 2E shows the memory device 200 after further phases of manufacture. Slits 260 are etched through the memory stack 210, down to the substrate 202. Each memory hole 220 is between two slits 260. The slits 260 provide access to the silicon nitride layers 214 of the memory stack 210. The silicon nitride layers 214 of the memory stack 210 are removed. In an example, the silicon nitride layers 214 of the memory stack 210 are removed by exposure to an acid, such as phosphoric acid via the slits 260.

Word lines 216 are formed between the silicon oxide layers 212 in the spaces created by removal of the silicon nitride layers 214. An aluminum oxide (such as Al₂O₃) layer is deposited on the exposed surfaces of the silicon oxide layers 212 and on the exposed surfaces of the silicon oxide of the first liner layer 222A. A titanium nitride layer is deposited onto the aluminum oxide layer. Then tungsten is deposited to fill the word lines 216.

Thereafter, any titanium nitride and tungsten that had been deposited in the slits 260 are removed. In an example, tungsten in the slits 260 is removed by a treatment including one or more of hydrofluoric acid or an iodine-containing acid. In another example, titanium nitride in the slits 260 is removed by a treatment including one or more of hydrogen peroxide or an inorganic acid (such as hydrofluoric acid). In some embodiments that may be combined with other embodiments, the aluminum oxide remains deposited on exposed surfaces of the slits 260. After removing titanium nitride and tungsten from the slits 260, the slits 260 are filled with a dielectric film 262 (such as a silicon oxide, such as SiO₂).

FIG. 2F shows the memory device 200 after further phases of manufacture. A metalized layer 270 is deposited onto the memory stack 210 and onto the dielectric film 262 that fills the slits 260. The metalized layer 270 may contain any one or more of aluminum, nickel, chromium, gold, germanium, copper, silver, titanium, tungsten, platinum, tantalum, or alloys thereof. The metalized layer 270 includes a contact 274 and a bit line 272. The contact 274 is metallic, for example copper or tungsten. The contact 274 forms an electrical connection between the doped upper portion 244 of the channel material 230 and the bit line 272. In an example that may be combined with other examples, the bit line 272 is made of copper.

At the back side 206 (opposite the front side 204) of the substrate 202, a portion of the substrate 202 is removed, such as by polishing, such as by chemical mechanical polishing, to expose the channel material 230 within the part of the memory hole 220 that extends into the substrate 202. Then, N+ doped silicon 208 (such as N+ doped polysilicon) is deposited on the back side 206 of the substrate 202. In an example, the dopant is one or more of phosphorus, arsenic, or antimony.

In some embodiments that may be combined with other embodiments, the memory device 200 is then bonded to a peripheral device, such as a peripheral wafer. In an example, the memory device 200 is bonded to a peripheral wafer by copper-to-copper hybrid bonding at the bit line 272 of the memory device 200.

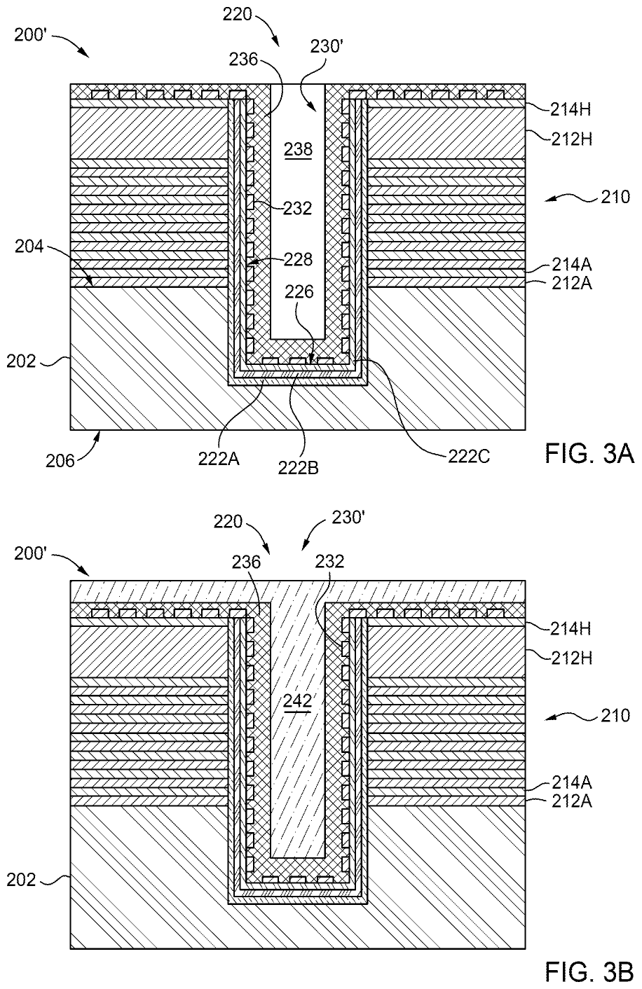

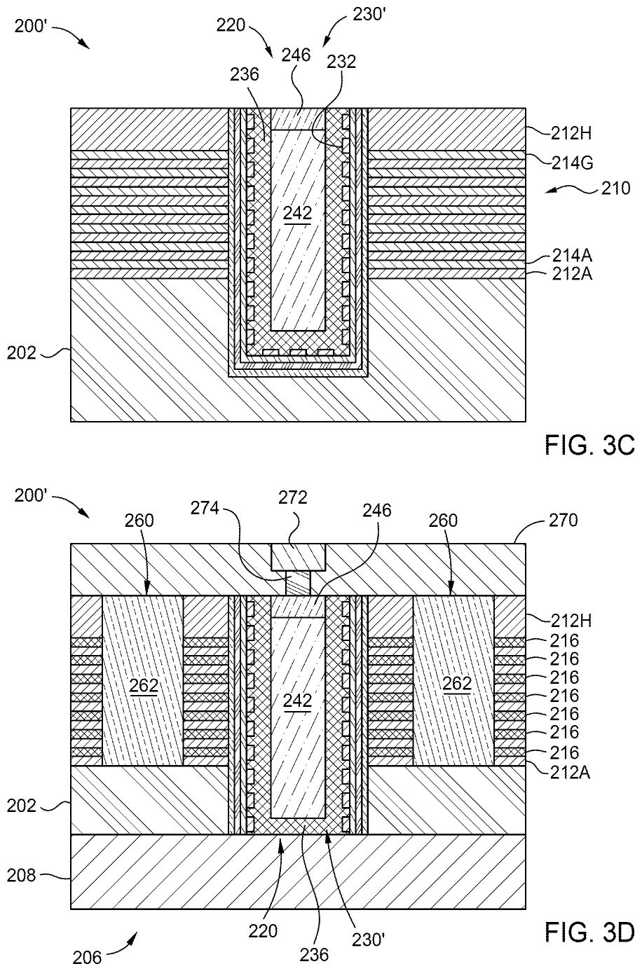

FIGS. 3A to 3D schematically illustrate a cross-section of a portion of a memory device 200′ at various phases of manufacture. Memory device 200′ may represent the memory device 100 of FIG. 1. Features of memory device 200′ that are similar to corresponding features of memory device 200 retain the same reference numerals without further description.

FIG. 3A shows a channel material 230′ deposited in the memory hole 220. The channel material 230′ includes the seed layer 232, as described above. The seed layer 232 is formed and then etched, as described above. The channel material 230′ includes a channel material layer 236 that is deposited in the memory hole 220 after the seed layer 232 has been etched. The channel material layer 236 is similar to the fill material 234 of memory device 200, and may be formed in a similar way as the fill material 234 of memory device 200.

Deposition of the channel material layer 236 includes growing crystals, such as silicon crystals. In embodiments in which the seed layer 232 includes one or more other substances, such as germanium, the crystals may include germanium crystals or SiGe crystals. The particles of the seed layer 232 remaining after the etching operation act as nuclei for growing the crystals. Although the seed layer 232 is depicted in the Figure, in some embodiments that may be combined with other embodiments, the seed layer 232 effectively becomes part of the channel material layer 236.

A thickness of the channel material layer 236 is from about 5 nm to about 25 nm, such as from about 10 nm to about 20 nm, such as from about 12 nm to about 18 nm, such as about 15 nm. The channel material layer 236 surrounds a void 238. The void 238 runs axially along at least a portion of the memory hole 220.

FIG. 3B shows a core material 242 having been deposited in the void 238. In some embodiments that may be combined with other embodiments, the core material 242 fills the void 238. In some embodiments that may be combined with other embodiments, the core material 242 does not fill the void 238. The core material 242 is a dielectric, such as a silicon oxide, such as SiO₂.

FIG. 3C shows the memory device 200′ after further phases of manufacture. The memory device 200′ is shown having undergone a planarization process. Planarization, such as by chemical mechanical polishing, removes extraneous material that had been deposited on the top of the memory device 200′. As illustrated, the planarization removes also the uppermost silicon nitride layer 214H of the memory stack 210, leaving the uppermost silicon oxide layer 212H exposed.

Thereafter, an upper portion of the core material 242 is removed, such as by performing a diffusion-limited etch. Then N+ doped silicon 246 (such as N+ doped polysilicon) is deposited onto the remaining portion of the core material 242 to fill remaining space within the memory hole 220. In an example, the dopant is one or more of phosphorus, arsenic, or antimony.

FIG. 3D shows the memory device 200′ after further phases of manufacture. The further phases are similar to the phases described above with respect to the manufacture of the memory device 200, including the provision of the slits 260, the removal of the silicon nitride layers 214, the formation of the word lines 216, and the filling of the slits 260. The further phases include also the forming of the metalized layer 270 (including the contact 274 and the bit line 272), such as described above. The contact 274 forms an electrical connection between the N+ doped silicon 246 and the bit line 272. The further phases include also the removing of a portion of the substrate 202 at the back side 206 of the substrate 202, and the deposition of N+ doped silicon 208 (such as N+ doped polysilicon) on the back side 206 of the substrate 202, such as described above.

In some embodiments that may be combined with other embodiments, the memory device 200′ is then bonded to a peripheral device, such as a peripheral wafer. In an example, the memory device 200′ is bonded to a peripheral wafer by copper-to-copper hybrid bonding at the bit line 272 of the memory device 200′.

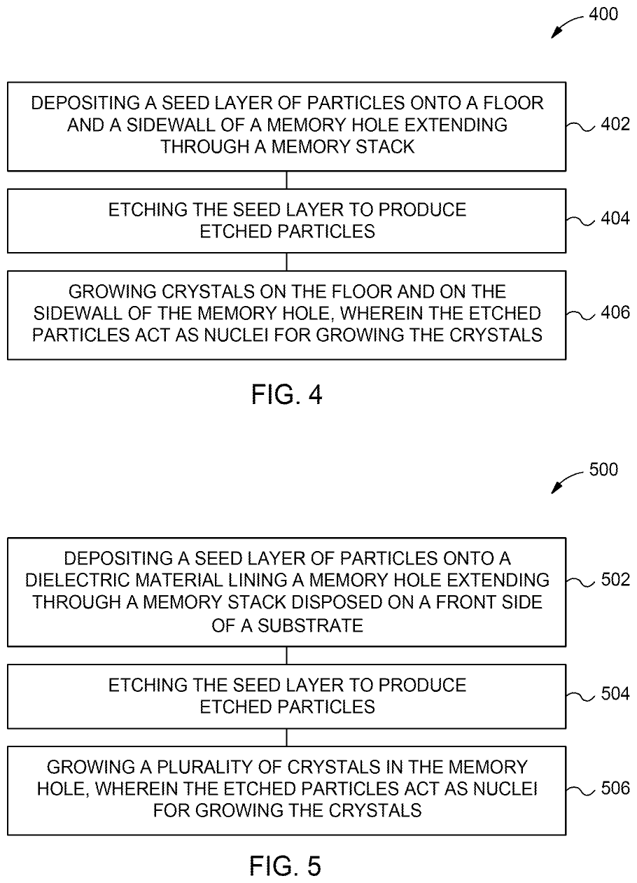

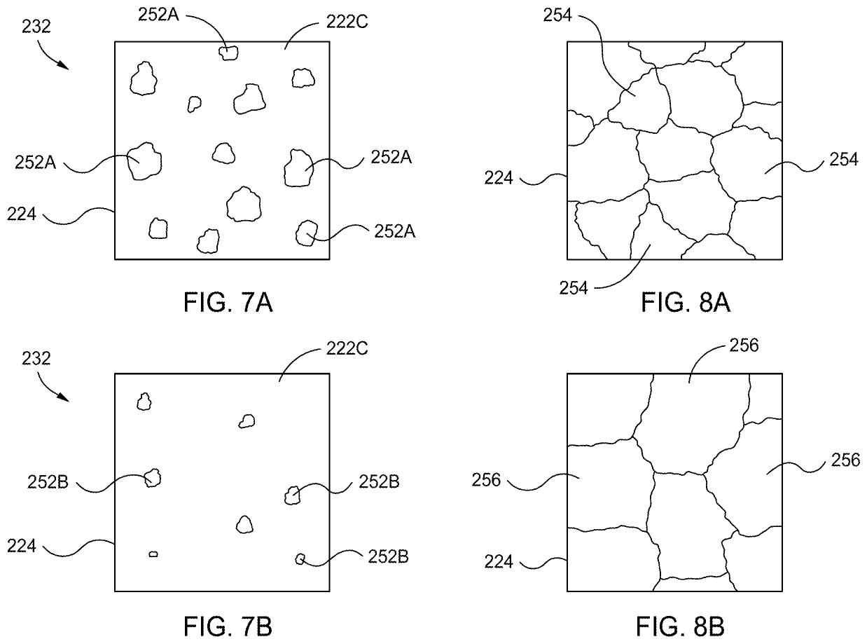

FIG. 4 is a flow diagram of a method of processing a substrate (such as substrate 102, 202). At operation 402, a seed layer (such as seed layer 232) of particles (such as particles 252A, FIG. 7A) is deposited onto a floor (such as floor 226) and a sidewall (such as sidewall 228) of a memory hole (such as memory hole 120, 220) extending through a memory stack (such as memory stack 110, 210). In some embodiments that may be combined with other embodiments, the particles of the seed layer include silicon. In some embodiments that may be combined with other embodiments, the particles of the seed layer may include one or more other substances, such as germanium. Depositing the seed layer may be performed by a thermal chemical deposition process, such as described above.

At operation 404, the seed layer is etched to produce etched particles (such as etched particles 252B, FIG. 7B). The etching operation may be performed as described above. In some embodiments that may be combined with other embodiments, the etching operation reduces an average size of the particles to produce the etched particles. In some embodiments that may be combined with other embodiments, the etching operation reduces an area number density of the particles to produce the etched particles.

At operation 406, crystals (such as crystals 256, FIG. 8B) are grown on the floor and on the sidewall of the memory hole. The etched particles act as nuclei for growing the crystals. In some embodiments that may be combined with other embodiments, the crystals comprise silicon. In embodiments in which the seed layer includes one or more other substances, such as germanium, the crystals may include germanium crystals or SiGe crystals. Growing the crystals may be performed by a thermal chemical deposition process, such as described above.

In some embodiments that may be combined with other embodiments, the crystals in the memory hole form a layer (such as channel material layer 236) surrounding a void (such as void 238). In some embodiments that may be combined with other embodiments, operation 406 includes depositing a core material (such as core material 242) in the void.

In some embodiments that may be combined with other embodiments, operations 402 and 404 are performed in the same processing chamber. In some embodiments that may be combined with other embodiments, operations 402 and 404 are performed in different processing chambers. In some embodiments that may be combined with other embodiments, operations 404 and 406 are performed in the same processing chamber. In some embodiments that may be combined with other embodiments, operations 404 and 406 are performed in different processing chambers.

In some embodiments that may be combined with other embodiments, method 400 includes performing an annealing operation on the memory stack. In an example that may be combined with other examples, the annealing operation is performed at a temperature of from about 500° C. to about 1200° C. for a duration ranging from about 1 minute to about 3 hours. In an example that may be combined with other examples, the annealing operation is performed between operations 402 and 404. In an example that may be combined with other examples, the annealing operation is performed between operations 404 and 406. In an example that may be combined with other examples, the annealing operation is performed after operation 406.

In some embodiments that may be combined with other embodiments, method 400 may incorporate any one or more of the operations, processes, or phases described above with respect to FIGS. 2A-2F or FIGS. 3A-3D.

FIG. 5 is a flow diagram of a method of processing a substrate (such as substrate 102, 202). At operation 502, a seed layer (such as seed layer 232) of particles (such as particles 252A, FIG. 7A) is deposited onto a dielectric material (such as third liner layer 222C) lining a memory hole (such as memory hole 120, 220) extending through a memory stack (such as memory stack 110, 210) disposed on a front side of the substrate. In some embodiments that may be combined with other embodiments, the particles of the seed layer include silicon. In some embodiments that may be combined with other embodiments, the particles of the seed layer may include one or more other substances, such as germanium. Depositing the seed layer may be performed by a thermal chemical deposition process, such as described above.

At operation 504, the seed layer is etched to produce etched particles (such as etched particles 252B, FIG. 7B). The etching operation may be performed as described above. In some embodiments that may be combined with other embodiments, the etching operation reduces an average size of the particles to produce the etched particles. In some embodiments that may be combined with other embodiments, the etching operation reduces an area number density of the particles to produce the etched particles.

At operation 506, a plurality of crystals (such as crystals 256, FIG. 8B) is grown in the memory hole. The etched particles act as nuclei for growing the crystals. In some embodiments that may be combined with other embodiments, the crystals comprise silicon. In embodiments in which the seed layer includes one or more other substances, such as germanium, the crystals may include germanium crystals or SiGe crystals. Growing the crystals may be performed by a thermal chemical deposition process, such as described above.

In some embodiments that may be combined with other embodiments, the crystals in the memory hole form a layer (such as channel material layer 236) surrounding a void (such as void 238). In some embodiments that may be combined with other embodiments, operation 506 includes depositing a core material (such as core material 242) in the void.

In some embodiments that may be combined with other embodiments, operations 502 and 504 are performed in the same processing chamber. In some embodiments that may be combined with other embodiments, operations 502 and 504 are performed in different processing chambers. In some embodiments that may be combined with other embodiments, operations 504 and 506 are performed in the same processing chamber. In some embodiments that may be combined with other embodiments, operations 504 and 506 are performed in different processing chambers.

In some embodiments that may be combined with other embodiments, method 500 includes performing an annealing operation on the memory stack. In an example that may be combined with other examples, the annealing operation is performed at a temperature of from about 500° C. to about 1200° C. for a duration ranging from about 1 minute to about 3 hours. In an example that may be combined with other examples, the annealing operation is performed between operations 502 and 504. In an example that may be combined with other examples, the annealing operation is performed between operations 504 and 506. In an example that may be combined with other examples, the annealing operation is performed after operation 506.

In some embodiments that may be combined with other embodiments, the memory hole includes a lower portion extending into the substrate. In some embodiments that may be combined with other embodiments, a portion of the seed layer is deposited in the lower portion of the memory hole. In some embodiments that may be combined with other embodiments, a crystal of the plurality of crystals is grown in the lower portion of the memory hole. In some embodiments that may be combined with other embodiments, method 500 includes removing a portion of the substrate from a back side of the substrate opposite the front side to expose the crystal grown in the lower portion of the memory hole.

In some embodiments that may be combined with other embodiments, method 500 may incorporate any one or more of the operations, processes, or phases described above with respect to FIGS. 2A-2F or FIGS. 3A-3D.

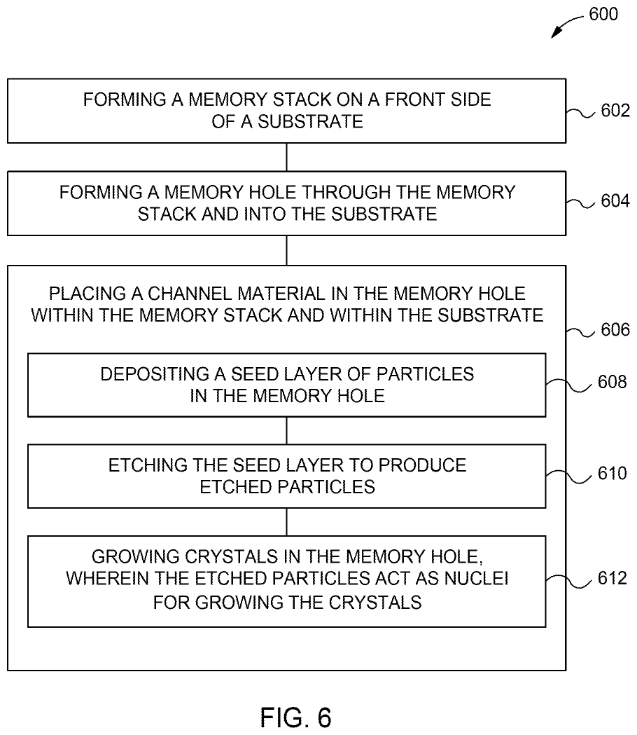

FIG. 6 is a flow diagram of a method of manufacturing a memory device (such as any of memory devices 100, 200, or 200′). At operation 602, a memory stack (such as memory stack 110, 210) is formed on a front side of a substrate (such as substrate 102, 202). At operation 604, a memory hole (such as memory hole 120, 220) is formed through the memory stack and into the substrate.

At operation 606, a channel material (such as channel material 130, 230, 230′) is placed in the memory hole within the memory stack and within the substrate. Operation 606 involves performing operations 608, 610, and 612. At operation 608, a seed layer (such as seed layer 232) of particles (such as particles 252A, FIG. 7A) is deposited in the memory hole. In some embodiments that may be combined with other embodiments, the particles of the seed layer include silicon. In some embodiments that may be combined with other embodiments, the particles of the seed layer may include one or more other substances, such as germanium. Depositing the seed layer may be performed by a thermal chemical deposition process, such as described above.

At operation 610, the seed layer is etched to produce etched particles (such as etched particles 252B, FIG. 7B). The etching operation may be performed as described above. In some embodiments that may be combined with other embodiments, the etching operation reduces an average size of the particles to produce the etched particles. In some embodiments that may be combined with other embodiments, the etching operation reduces an area number density of the particles to produce the etched particles.

At operation 612, crystals (such as crystals 256, FIG. 8B) are grown in the memory hole. The etched particles act as nuclei for growing the crystals. In some embodiments that may be combined with other embodiments, the crystals comprise silicon. In embodiments in which the seed layer includes one or more other substances, such as germanium, the crystals may include germanium crystals or SiGe crystals. Growing the crystals may be performed by a thermal chemical deposition process, such as described above.

In some embodiments that may be combined with other embodiments, the crystals in the memory hole form a layer (such as channel material layer 236) surrounding a void (such as void 238). In some embodiments that may be combined with other embodiments, operation 606 includes depositing a core material (such as core material 242) in the void.

In some embodiments that may be combined with other embodiments, operations 608 and 610 are performed in the same processing chamber. In some embodiments that may be combined with other embodiments, operations 608 and 610 are performed in different processing chambers. In some embodiments that may be combined with other embodiments, operations 610 and 612 are performed in the same processing chamber. In some embodiments that may be combined with other embodiments, operations 610 and 612 are performed in different processing chambers.

In some embodiments that may be combined with other embodiments, method 600 includes performing an annealing operation on the memory stack. In an example that may be combined with other examples, the annealing operation is performed at a temperature of from about 500° C. to about 1200° C. for a duration ranging from about 1 minute to about 3 hours. In an example that may be combined with other examples, the annealing operation is performed between operations 608 and 610. In an example that may be combined with other examples, the annealing operation is performed between operations 610 and 612. In an example that may be combined with other examples, the annealing operation is performed after operation 612.

In some embodiments that may be combined with other embodiments, method 600 includes removing a portion of the substrate from a back side of the substrate opposite the front side to expose a portion of the channel material within the substrate.

In some embodiments that may be combined with other embodiments, method 600 may incorporate any one or more of the operations, processes, or phases described above with respect to FIGS. 2A-2F or FIGS. 3A-3D.

In some embodiments that may be combined with other embodiments, any one or more of the operations of method 400 may be incorporated into method 500. In some embodiments that may be combined with other embodiments, any one or more of the operations of method 400 may be incorporated into method 600. In some embodiments that may be combined with other embodiments, any one or more of the operations of method 500 may be incorporated into method 400. In some embodiments that may be combined with other embodiments, any one or more of the operations of method 500 may be incorporated into method 600. In some embodiments that may be combined with other embodiments, any one or more of the operations of method 600 may be incorporated into method 400. In some embodiments that may be combined with other embodiments, any one or more of the operations of method 600 may be incorporated into method 500.

FIGS. 7A and 7B schematically represent the particles of the seed layer 232 respectively before and after the etching operation. FIGS. 7A and 7B represent a view of a portion of the seed layer 232 normal to the third liner layer 222C on which the seed layer 232 is deposited. FIG. 7A represents the portion of the seed layer 232 prior to the etching operation. Twelve particles 252A are depicted in an area 224 of the third liner layer 222C. The particles 252A are depicted as having various shapes and sizes. FIG. 7B represents the portion of the seed layer 232 of FIG. 7A after the etching operation. Five of the particles 252A in the area 224 have been etched away completely. The remaining seven particles 252A of FIG. 7A in the area 224 have been etched to form etched particles 252B. Each etched particle 252B has been reduced in size.

FIGS. 8A and 8B schematically represent comparisons of crystal sizes and numbers for channel material deposited under two different scenarios. FIG. 8A represents a scenario in which the etching operation of the seed layer 232 is omitted. FIG. 8A illustrates a simulation of crystals 254 grown in the area 224 on the portion of the seed layer 232 depicted in FIG. 7A. FIG. 8B represents a scenario in which the etching operation of the seed layer 232 is performed prior to growing crystals. FIG. 8B illustrates a simulation of crystals 256 grown in the area 224 on the portion of the seed layer 232 depicted in FIG. 7B following the etching operation of the seed layer 232. FIG. 8A shows more crystals and generally smaller crystals than FIG. 8B.

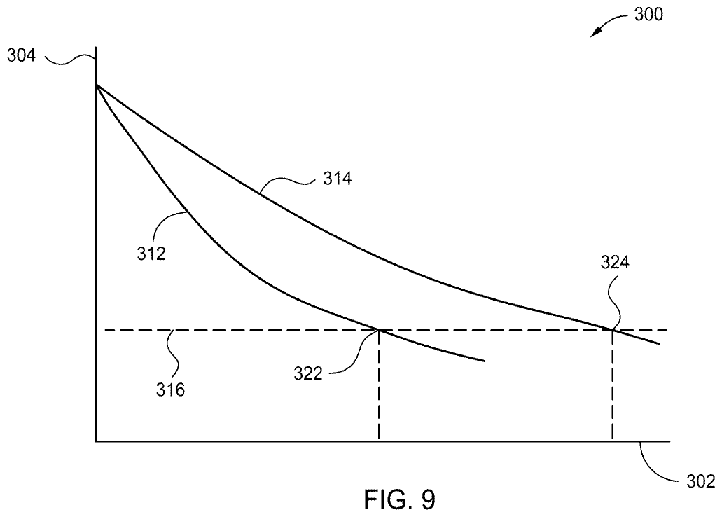

FIG. 9 is a graph 300 that schematically represents an effect of the different crystal structures of FIGS. 8A and 8B on a string current conveyed through the channel material of a memory hole (such as memory hole 120, 220). The x axis 302 represents a length of a memory hole containing a channel material. The y axis 304 represents a string current through the channel material. The line 312 represents how the magnitude of an example string current through channel material made up of crystals 254 as depicted in FIG. 8A varies with the length of the memory hole. The line 314 represents how the magnitude of an example string current through channel material made up of crystals 256 as depicted in FIG. 8B varies with the length of the memory hole. For any given length of memory hole, the crystals 256 of FIG. 8B facilitate the passage of a higher string current through the channel material than do the crystals 254 of FIG. 8A. The higher string current promotes memory devices incorporating channel material made up of crystals 256 as depicted in FIG. 8B to be more reliable than memory devices incorporating channel material made up of crystals 254 as depicted in FIG. 8A.

Furthermore, the line 316 represents a lower threshold string current, below which the corresponding memory device may not function effectively. For example, a string current below the lower threshold 316 may not be detected, or may otherwise result in errors when a processor attempts to read the memory stored on the memory device. The point of intersection 322 of the threshold 316 with line 312 represents an effective maximum length of memory holes having channel material made up of crystals 254 as depicted in FIG. 8A. The point of intersection 324 of the threshold 316 with line 314 represents an effective maximum length of memory holes having channel material made up of crystals 256 as depicted in FIG. 8B.

It can be seen that the maximum effective length of memory holes having channel material made up of crystals 256 as depicted in FIG. 8B may be greater than for memory holes having channel material made up of crystals 254 as depicted in FIG. 8A. Memory devices incorporating channel material made up of crystals 256 as depicted in FIG. 8B may be constructed to have greater memory capacity than memory devices incorporating channel material made up of crystals 254 as depicted in FIG. 8A.

Without being bound by theory, it is considered that electron mobility in the channel material is dependent on the size of the crystals 254, 256. In an example, electron mobility within a crystal 254, 256 is greater than electron mobility between crystals across a grain boundary. A given length of channel material having the smaller crystals 254 of FIG. 8A would include more grain boundaries than channel material having the larger crystals 256 of FIG. 8B. Consequently, electrons traveling through the channel material having the smaller crystals 254 of FIG. 8A would be subject to greater resistance than electrons traveling through the channel material having the larger crystals 256 of FIG. 8B, resulting in the effects and implications discussed above.

Aspects of the present disclosure provide methods for manufacturing memory devices in which the channel material in memory holes is configured to convey string currents more effectively than the channel material in conventional memory devices. The channel material of the present disclosure facilitates the manufacture of memory devices having longer memory holes, thinner memory holes, and memory holes more closely spaced than conventional memory devices.

The channel material of the present disclosure may be produced by a thermal chemical deposition process, such as chemical vapor deposition. The use of such a process for producing the channel material is advantageous over an alternative epitaxial process. For example, epitaxial deposition of silicon requires the silicon to be deposited directly onto a silicon substrate, which necessitates selective removal of the liner layers at the floor of each memory hole. Such a selective removal—without removal of the liner layers from the sidewall of each memory hole—is difficult to achieve with longer and thinner memory holes. Furthermore, the epitaxial deposition process itself consumes more energy and is more expensive than the thermal chemical deposition processes contemplated in the present disclosure. The methods of the present disclosure are more suitable than an epitaxial process for producing memory devices of increasingly greater memory capacity at a quality and a cost better than, or equivalent to, the quality and cost of present-day memory devices.

It is contemplated that any one or more elements or features of any one disclosed embodiment may be beneficially incorporated in any one or more other non-mutually exclusive embodiments. While the foregoing is directed to embodiments of the present disclosure, other and further embodiments of the disclosure may be devised without departing from the basic scope thereof, and the scope thereof is determined by the claims that follow.

What is claimed is:

1. A substrate processing method, comprising:
depositing a seed layer of particles onto a floor and a sidewall of a memory hole extending through a memory stack;
etching the seed layer to produce etched particles; and
growing crystals on the floor and on the sidewall of the memory hole, wherein the etched particles act as nuclei for growing the crystals.

2. The method of claim 1, wherein etching the seed layer reduces an area number density of the particles in producing the etched particles.

3. The method of claim 1, wherein etching the seed layer reduces an average size of the particles in producing the etched particles.

4. The method of claim 1, wherein etching the seed layer comprises exposing the seed layer to hydrochloric acid.

5. The method of claim 1, wherein:
the seed layer and the crystals comprise silicon; and
depositing the seed layer comprises exposing the memory hole to a silicon precursor in a hydrogen environment at about 400° C. to about 1100° C.

6. The method of claim 5, wherein the silicon precursor includes at least one of silane, dichlorosilane (DCS), trichlorosilane (TCS), or a silene.

7. The method of claim 1, wherein the crystals in the memory hole form a layer surrounding a void.

8. The method of claim 7, further comprising depositing a core material in the void.

9. The method of claim 8, wherein the crystals are silicon, and the core material is a silicon oxide.

10. The method of claim 1, further comprising performing an annealing operation on the memory stack at about 500° C. to about 1200° C. for a duration ranging from about 1 minute to about 3 hours.

11. The method of claim 10, wherein the annealing operation is performed:
between depositing the seed layer and growing the crystals; or
after growing the crystals.

12. A substrate processing method, comprising:
depositing a seed layer of particles onto a dielectric material lining a memory hole extending through a memory stack disposed on a front side of a substrate;
etching the seed layer to produce etched particles; and
growing a plurality of crystals in the memory hole, wherein the etched particles act as nuclei for growing the crystals.

13. The method of claim 12, wherein the memory hole includes a lower portion extending into the substrate.

14. The method of claim 13, wherein a portion of the seed layer is deposited in the lower portion of the memory hole.

15. The method of claim 14, wherein a crystal of the plurality of crystals is grown in the lower portion of the memory hole.

16. The method of claim 15, further comprising removing a portion of the substrate from a back side of the substrate opposite the front side, thereby exposing the crystal grown in the lower portion of the memory hole.

17. The method of claim 12, wherein the crystals in the memory hole form a layer surrounding a void.

18. The method of claim 16, further comprising depositing a core material in the void.

19. A method of manufacturing a memory device, comprising:
forming a memory stack on a front side of a substrate;
forming a memory hole through the memory stack and into the substrate; and
placing a channel material in the memory hole within the memory stack and within the substrate by:
depositing a seed layer of particles in the memory hole;
etching the seed layer to produce etched particles; and
growing crystals in the memory hole, wherein the etched particles act as nuclei for growing the crystals.

20. The method of claim 19, further comprising removing a portion of the substrate from a back side of the substrate opposite the front side, thereby exposing a portion of the channel material within the substrate.
